(19) United States
(12) Patent Application Publication
(10) Pub. No.: US 2021/0352389 A1
(43) Pub. Date: Nov. 11, 2021

(54) ELECTRONIC DEVICE AND CONTROL METHOD THEREOF

(71) Applicant: SAMSUNG ELECTRONICS CO., LTD., Suwon-si (KR)

(72) Inventor: Seungho LEE, Suwon-si (KR)

(73) Assignee: SAMSUNG ELECTRONICS CO., LTD., Suwon-si (KR)

(21) Appl. No.: 17/277,824

(22) PCT Filed: Jun. 26, 2019
(86) PCT No.: PCT/KR2019/007746

§ 371 Date: Mar. 19, 2021

(30) Foreign Application Priority Data
Nov. 8, 2018 (KR) 10-2018-0136304

(51) Int. Cl. H04R 1/02; H04R 1/28; H04R 3/04; H03G 3/30; H03F 3/183

(52) U.S. Cl. CPC H04R 1/025; H04R 1/2834; H04R 2499/15; H03G 3/3015; H03F 3/183; H04R 3/04

(57) ABSTRACT

The disclosure relates to an electronic apparatus including: a speaker including a transducer provided in an enclosure of a housing and configured to perform an amplitude movement based on a first driving signal, and an active radiator configured to perform an amplitude movement based on a rear wave due to the amplitude movement of the transducer and a second driving signal; and an amplifier configured to output the first driving signal corresponding to the sound signal and the second driving signal which complements the amplitude movement of the active radiator based on the rear wave of the transducer and allows an output sound pressure of the active radiator to be a target value.

### TECHNICAL FIELD

The disclosure relates to an electronic apparatus and a control method thereof for enhancing bass sound, more specifically, an electronic apparatus and a control method thereof to complement amplitude movement of an active radiator and allow output sound pressure of the active radiator to be a target value.

### BACKGROUND ART

Recently, a passive radiator speaker for enhancing bass component has been widely used. The passive radiator speaker is a kind of a bass-reflex speaker which is capable of enhancing a level of the bass component and expanding a low frequency range by allowing a passive radiator, which has no magnetic circuit, to be resonant in the low frequency range with a rear wave occurring by amplitude movement of a transducer through air that is sealed in an enclosure.

The enhancement of the bass component by the passive radiator speaker is more effective as the size of the transducer and the enclosure becomes larger, but because the size of the transducer and the enclosure is restricted in accordance with the trend where the passive radiator speaker becomes smaller and slimmer, the bass component has not been enhanced effectively. For example, the passive radiator speaker may be installed in a thin flat screen television or be embodied as an ultra-small portable speaker, where there occurs a phenomenon that compliance of air-suspension for the amplitude movement decreases due to the restriction of the size of the enclosure. Here, the compliance refers to flexibility or conformability to the amplitude movement. The decrease of the compliance of the air-suspension impedes the amplitude movement of the transducer and prevents the rear wave from being output sufficiently, which adversely affects the passive radiator to output the bass component.

Therefore, although the size of the transducer and the enclosure is restricted in accordance with the trend where the passive radiator becomes smaller and slimmer, a solution to enhance and output the bass component effectively is required.

### TECHNICAL PROBLEM

Accordingly, an aspect of the disclosure is to provide an electronic apparatus and a control method thereof to enhance and output the bass component effectively, although the size of the transducer and the enclosure is restricted in accordance with the trend where the passive radiator becomes smaller and slimmer.

### TECHNICAL SOLUTION

According to an embodiment of the disclosure, there is provided an electronic apparatus including: a housing; a speaker provided in an enclosure of the housing and configured to output a sound wave based on a sound signal, the speaker including a transducer configured to perform an amplitude movement based on a first driving signal, and an active radiator configured to perform an amplitude movement based on a rear wave due to the amplitude movement of the transducer and a second driving signal; and an amplifier configured to output the first driving signal corresponding to the sound signal and the second driving signal which complements the amplitude movement of the active radiator based on the rear wave of the transducer and allows an output sound pressure of the active radiator to be a target value.

Here, the electronic apparatus may further include a filter configured to perform a filtering with respect to a frequency range of the sound signal to allow the second driving signal to have the frequency range.

Here, the frequency range may be determined by at least one of weight of a vibration system of the active radiator or air volume in the enclosure.

Here, the target value of the output sound pressure of the active radiator may be determined by excluding a portion due to the output sound pressure of the transducer from a target value of a total output sound pressure of the speaker.

Here, a level of the second driving signal may be determined such that a sum of the amplitude movement of the active radiator due to the rear wave and the amplitude movement of the active radiator due to the second driving signal corresponds to the output sound pressure having the target value.

Here, the electronic apparatus may further include a display of a panel shape, wherein the housing may have a rear face covering rear of the display, and the enclosure may be provided between the rear face of the housing and the display.

Also, according to an embodiment of the disclosure, there is provided an electronic apparatus including: a signal output part configured to output a first driving signal and a second driving signal to a speaker, the speaker including a transducer configured to perform an amplitude movement based on the first driving signal, and an active radiator configured to perform an amplitude movement based on a rear wave due to the amplitude movement of the transducer and the second driving signal; and an amplifier configured to perform a signal process to output through the signal output part the first driving signal corresponding to a sound signal and the second driving signal which complements the amplitude movement of the active radiator based on the rear wave of the transducer and allows an output sound pressure of the active radiator to be a target value.

Here, the electronic apparatus may further include a filter configured to perform a filtering with respect to a frequency range of the sound signal to allow the second driving signal to have the frequency range.

Here, the frequency range may be determined by at least one of weight of a vibration system of the active radiator or air volume in the enclosure.

Here, the target value of the output sound pressure of the active radiator may be determined by excluding a portion due to the output sound pressure of the transducer from a target value of a total output sound pressure of the speaker.

Here, a level of the second driving signal may be determined such that a sum of the amplitude movement of the active radiator due to the rear wave and the amplitude movement of the active radiator due to the second driving signal corresponds to the output sound pressure having the target value.

Also, according to an embodiment of the disclosure, there is a speaker including: an enclosure; a transducer provided in the enclosure and configured to perform an amplitude movement based on a first driving signal; an active radiator provided in the enclosure and configured to perform an amplitude movement based on a rear wave due to the amplitude movement of the transducer and a second driving signal; and an amplifier configured to output the first driving signal corresponding to a sound signal which is input and the second driving signal which complements the amplitude movement of the active radiator based on the rear wave of the transducer and allows an output sound pressure of the active radiator to be a target value.

Here, the speaker may further include a filter configured to perform a filtering with respect to a frequency range of the sound signal to allow the second driving signal to have the frequency range.

Here, the frequency range may be determined by at least one of weight of a vibration system of the active radiator or air volume in the enclosure.

Here, the target value of the output sound pressure of the active radiator may be determined by excluding a portion due to the output sound pressure of the transducer from a target value of a total output sound pressure of the speaker.

Here, a level of the second driving signal may be determined such that a sum of the amplitude movement of the active radiator due to the rear wave and the amplitude movement of the active radiator due to the second driving signal corresponds to the output sound pressure having the target value.

### ADVANTAGEOUS EFFECTS

According to the disclosure, it is possible to provide an electronic apparatus and a control method thereof to enhance and output the bass component effectively, although the size of the transducer and the enclosure is restricted in accordance with the trend where the passive radiator becomes smaller and slimmer.

### DESCRIPTION OF DRAWINGS

FIG. 1 illustrates an electronic apparatus according to an embodiment of the disclosure.

FIG. 2 illustrates an electronic apparatus according to another embodiment of the disclosure.

FIG. 3 illustrates an electronic apparatus according to still another embodiment of the disclosure.

FIG. 4 illustrates an example of the speaker of FIGS. 1 to 3.

FIG. 5 illustrates an example of the active radiator of FIGS. 1 to 3.

FIG. 6 illustrates an example where the target value sound pressure is output by the active driving of FIG. 4.

FIG. 7 illustrates another example where the target value sound pressure is output by the active driving of FIG. 4.

### BEST MODE

Below, various embodiments of the disclosure will be described with reference to accompanying drawings. The following embodiments have to be considered as illustrative only, and it should be construed that all suitable modification, equivalents and/or alternatives fall within the scope of the disclosure. Throughout the drawings, like numerals refer to like elements. In the disclosure, a term “at least one of” a plurality of elements or the like may not refer to all of the plurality of elements but also to each and every possible combination of the elements.

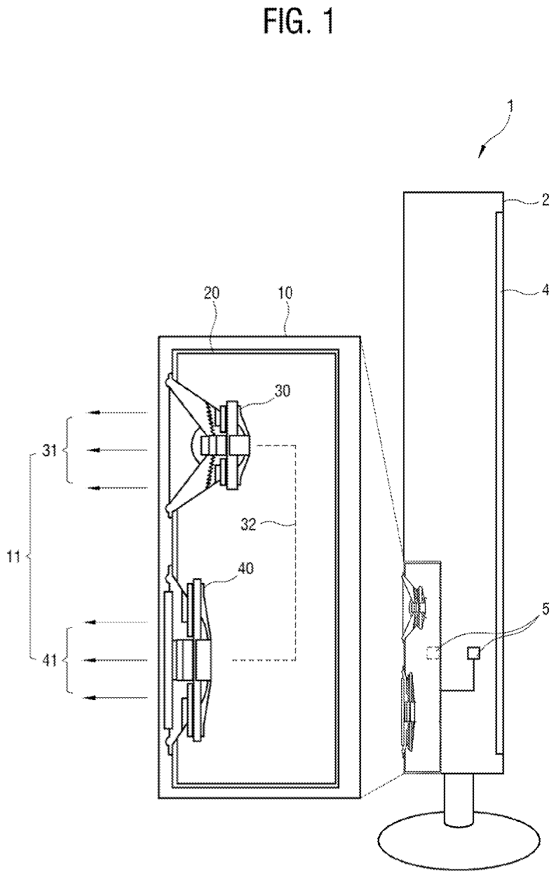

FIG. 1 illustrates an electronic apparatus 1 according to an embodiment of the disclosure. As illustrated in FIG. 1, the electronic apparatus 1 according to the embodiment outputs a sound wave. For example, in case of the electronic apparatus 1 being embodied as a television, the electronic apparatus 1 outputs the sound wave which corresponds to an image, while displaying the image on a display 4, or, as an audio device, only outputs the sound wave without displaying the image on the display 4. However, FIG. 1 does not limit the example of the electronic apparatus 1, and the electronic apparatus 1 may be embodied as an audio device, a smart phone, a tablet, a personal computer, a wearable device such a smart watch, a multimedia player, a home appliance such as a refrigerator, etc. which is capable of outputting the sound wave. Also, the apparatus according to the embodiment may be embodied as a separate speaker which receives a sound signal from the electronic apparatus 1 and outputs the sound wave. However, for the sake of description below, it will be described that the apparatus according to the embodiment is supposed to be embodied as the electronic apparatus 1 such as a television.

The electronic apparatus 1 according to the embodiment includes a housing 2, a speaker 10, and an amplifier 5. The housing 2 forms exterior of the electronic apparatus 1 and protects inside configuration of the electronic apparatus 1 from outside. For example, the housing 2 includes a front cover which covers a front face and a rear cover which covers a rear face, where the inside configuration is provided between the front cover and the rear cover. If the electronic apparatus 1 further includes the display 4 of a panel shape, the inside configuration is provided between the display 4 and the rear cover. For example, the speaker 10 or the amplifier 5 is provided between the display 4 and the rear cover to be protected from outside.

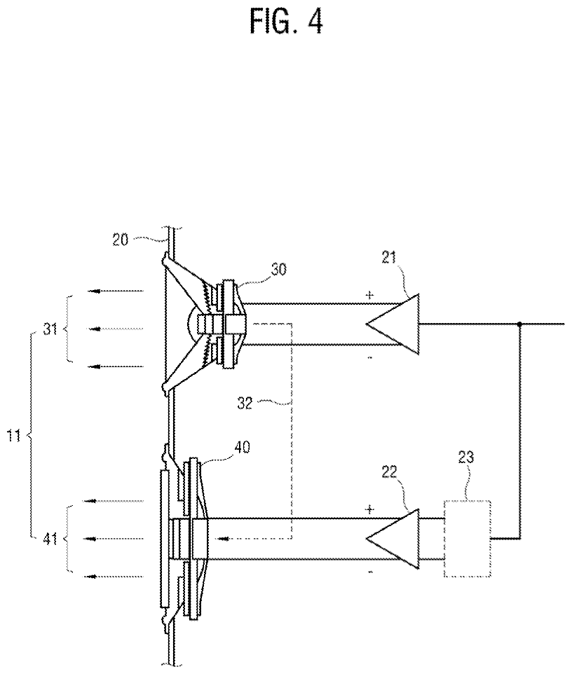

The speaker 10 outputs a total target value sound pressure 11. For this, the speaker 10 includes an enclosure 20, a transducer 30, and an active radiator 40. In FIG. 1, for the sake of illustration, a driving circuit for the transducer 30, etc. is omitted and will be described in detail referring to FIG. 4, etc.

The enclosure 20 receives air therein. The air in the enclosure 20 acts as a medium through which pressure that changes in accordance with a rear wave 32 of the transducer 30 is transferred to the active radiator 40. Also, the enclosure 20 forms a space that is sealed, accommodating the transducer 30 and the active radiator 40 in an area inside the space.

The transducer 30 is provided in the enclosure 20 and outputs sound pressure 31 based on a sound signal. The transducer 30 performs forward and backward amplitude movement according to the sound signal and generates a front wave 31 which is outward and a rear wave 32 which is inward.

The transducer 30 includes a magnet, a coil, and a diaphragm to output the sound wave. The magnet forms a magnetic field where the coil, of which the polarity changes according to the sound signal, performs the amplitude movement due to the changed polarity in the magnetic field, which also allows the diaphragm coupled with the coil to perform the amplitude movement and generates the front wave 31 and the rear wave 32. However, the configuration of the transducer 30 is not limited thereto and includes an edge which allows the diaphragm to perform the amplitude movement, a frame which fastens the transducer 30, a cap which protects foreign substance from flowing in, a damper which is provided between the diaphragm and the coil to adjust vibration of the diaphragm, etc.

The active radiator 40 is provided in the enclosure 20 together with the transducer 30 and reinforces a low frequency range of the output sound pressure 31 of the transducer 30. Specifically, the active radiator 40 outputs sound pressure due to passive driving based on the rear wave 32. When the air pressure in the enclosure 20 changes because of the rear wave 32 of the transducer 30, the active radiator 40 outputs the sound pressure by performing the amplitude movement in the low frequency range according to the change of the air pressure in the enclosure 20. In this way, what the active radiator 40 operates as a passive radiator to output the sound pressure is referred to as the passive driving.

Especially, the active radiator 40 according to the embodiment performs active driving to complement the amplitude movement due to the passive driving. The active driving allows the active radiator 40 to output target value sound pressure 41 by complementing the amplitude movement due to the passive driving and reinforcing the output sound pressure due to the passive driving. That is, the active radiator 40 allows the speaker 10 to output the total target value sound pressure 11 by outputting the target value sound pressure 41 through the passive driving and the active driving and reinforcing the low frequency range of the output sound pressure 31 of the transducer 30.

The amplifier 5 amplifies the level or the output of the input sound signal and outputs a driving signal to the speaker 10. The amplifier 5 outputs a first driving signal which corresponds to the sound signal to the transducer 30. The amplifier 5 outputs a second driving signal to the active radiator 40 and allows the active radiator 40 to reinforce the output sound pressure due to the passive driving through the active driving. That is, the second driving signal of the amplifier 5 allows the active radiator 40 to output the target value sound pressure 41 and reinforces the low frequency range of the output sound pressure 31 of the transducer 30, which allows the speaker 10 to output the total target value sound pressure 11.

Meanwhile, the amplifier 5 adjusts a predetermined gain to output the driving signal to the transducer 30 and the active radiator 40 so that the speaker 10 outputs the total target value sound pressure 11.

Although FIG. 1 illustrates that the amplifier 5 is provided at the electronic apparatus 1, FIG. 1 does not limit the position where the amplifier 5 is provided but the amplifier 5 may be provided at the speaker 10 in accordance with a design method.

Also, FIG. 1 does not limit the configurations of the electronic apparatus 1, and thus the electronic apparatus 1 may exclude some configurations shown in FIG. 1 or include another configuration not shown in FIG. 1. For example, the electronic apparatus 1 may further include at least one of a signal receiver, a signal processor, a display 4, a processor, a user input part, a power part or a storage.

The signal receiver receives a content signal which includes at least one of an image signal or a sound signal from outside. The signal receiver receives the content signal from a content provider such as a broadcaster or an external content source apparatus.

The signal processor performs a signal process on the content signal which is received from outside through the signal receiver or generated inside. The signal processor processes the image signal to display an image through the display 4 or output the sound wave through the speaker 10. When processing the sound signal, the signal processor provides the processed sound signal to the amplifier 5.

The signal process performed by the signal processor may include an image process such as decoding, de-interlacing, scaling, noise reduction, detail enhancement, etc. frequency modulation, conversion, mixing, etc., but is not limited thereto.

The display 4 displays an image based on the image signal which processed by the signal processor. Examples of the display 4 are not limited and may be embodied as liquid crystal, plasma, a light-emitting diode, an organic light-emitting diode, a surface-conduction electron-emitter, a carbon nano-tube, nano-crystal, etc.

The processor controls a general operation of the electronic apparatus 1. For example, the processor may control the speaker 10 to output the total target value sound pressure 11 based on the sound signal. More specifically, the processor may control the transducer 30 to output the sound pressure 31 based on the sound signal and the active radiator 40 to perform the active driving based on the sound signal. The processor allows the active radiator 40 to perform the active driving which reinforces the output sound pressure due to the passive driving and output the target value sound pressure 41.

However, the active radiator 40 is not limited to output the target value sound pressure 41 according to the control of the processor but the speaker 10 may have a predetermined gain that allows the active radiator 40 to output the target value sound pressure 41, which will be described in detail with reference to FIG. 4, etc.

The processor may include a control program (or an instruction) for performing the general control of the configurations, a nonvolatile memory in which the control program is installed, a volatile memory in which at least a part of the installed control program is loaded, and at least one processor or central processing unit (CPU) for executing the loaded control program. Further, such a control program may be stored in another electronic apparatus other than the electronic apparatus 1.

The control program may include a program(s) actualized in the form of at least one among a basis input/output system (BIOS), a device driver, an operating system, a firmware, a platform, and an application program. According to an embodiment, the application program may be previously installed or be stored when the display apparatus 20 is manufactured, or may be installed based on application data received from the outside when it is used in the future. The application data may, for example, be downloaded from a server such as an application market. Such a server is an example of a computer program product, but is not limited to this example.

Also, the processor may perform at least a part of data analysis, processing and result information generating for the speaker 10 to output the total target value sound pressure 11 or for the active radiator 40 to output the target value sound pressure 41 through the active driving by using as a rule-based or artificial intelligence algorithm at least one of machine learning, neural network, or deep learning.

Also, the user input part receives a user input and forwards the user input to the processor. The user input part may be embodied as various forms according to a type of the user input. For example, a menu button which is provided on an outside of the electronic apparatus 1, a touch screen which is provided on the display 4 and receives a user touch input, etc. The power part receives power from outside according to the control of the processor and provides the power needed to the configurations of the electronic apparatus 1, whereas the storage stores instructions, programs, applications, etc. to control the electronic apparatus 1. For example, the storage may include a recording medium of at least one type among a flash memory type, a hard disk type, a multimedia card micro type, a card type memory (such as a secure digital (SD) memory, an extreme digital (XD) memory, etc.), a random access memory (RAM), a static random access memory (SRAM), etc.

In this way, the electronic apparatus 1 according to the embodiment outputs the driving signal to the speaker 10 through the amplifier 5 and allows the active radiator 40 of the speaker 10 to output the target value sound pressure 41 by reinforcing the sound pressure due to the passive driving of the active radiator 40 through the active driving by which the active radiator 40 complements the passive driving. Therefore, although the size of the transducer 30 and the enclosure 20 is restricted, it is possible for the speaker 10 of the electronic apparatus 1 to output an enhanced bass component.

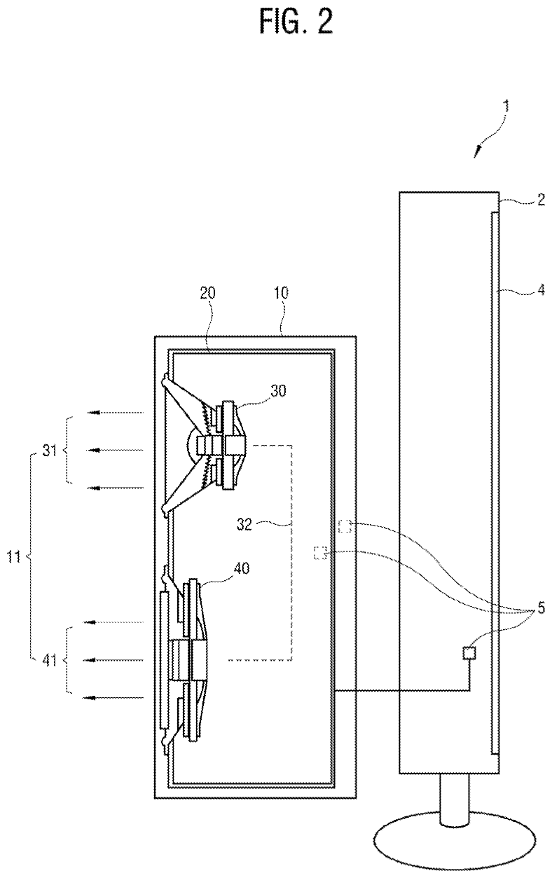

FIG. 2 illustrates an electronic apparatus 1 according to another embodiment of the disclosure. While the speaker 10 is provided at the electronic apparatus 1 in FIG. 1, the speaker 10 is differently provided outside the electronic apparatus 1 in FIG. 2. Below, the electronic apparatus 1 of FIG. 2 will be mainly described on differences from that of FIG. 1 and description redundant to FIG. 1 will be omitted.

As illustrated FIG. 2, the electronic apparatus 1 according to the embodiment outputs the sound wave through a speaker 10 which is provided outside the electronic apparatus 1. For example, the electronic apparatus 1 may be embodied as an audio device, a smart phone, a tablet, a personal computer, a wearable device such a smart watch, a multimedia player, a home appliance such as a refrigerator, etc. Also, the speaker 10 may be embodied as a separate speaker, a speaker unit, a speaker module, an ultra-small portable speaker, an artificial intelligence speaker, a home theater, etc.

Although FIG. 2 illustrates that the amplifier 5 is provided at the electronic apparatus 1, the position where the amplifier 5 is provided is not limited thereto and the amplifier 5 may be provided at the speaker 10. However, for the sake of description below, it is supposed that the amplifier 5 is provided at the electronic apparatus 1.

The electronic apparatus 1 according to the embodiment includes the housing 2 and the amplifier 5. The housing 2 forms exterior of the electronic apparatus 1 and, if the electronic apparatus 1 further include the display 4, the amplifier 5 is provided between the rear cover of the housing 2 and the display 4.

The amplifier 5 amplifies the level or the output of the sound signal and outputs a driving signal to the speaker 10 so that the speaker 10 outputs the total target value sound pressure 11. The amplifier 5 outputs the first driving signal which corresponds to the sound signal to the transducer 30 so that the transducer 30 of the speaker 10 outputs the sound pressure 31.

The amplifier 5 outputs the second driving signal to the speaker 10 and allows the active radiator 40 to reinforce the output sound pressure due to the passive driving through the active driving. That is, the active radiator 40 outputs the target value sound pressure 41 using the second driving signal output from the amplifier 5 and reinforces the low frequency range of the output sound pressure 31 of the transducer 30 so that the speaker 10 outputs the total target value sound pressure 11. The amplifier 5 adjusts a predetermined gain to output the driving signal to the transducer 30 and the active radiator 40 so that the speaker 10 outputs the total target value sound pressure 11.

Meanwhile, FIG. 2 does not limit the configurations of the electronic apparatus 1, and thus the electronic apparatus 1 may exclude a part of the configurations shown in FIG. 2 or include another configuration not shown in FIG. 2. For example, the electronic apparatus 1 may further include at least one of the signal receiver, the signal processor, the display 4, the processor, the user input part, the power part or the storage. However, the description on each configuration will be omitted because of redundancy to the description of FIG. 1.

In this way, the electronic apparatus 1 according to the embodiment outputs the driving signal to the speaker 10 through the amplifier 5 and allows the active radiator 40 of the speaker 10 to output the target value sound pressure 41 by reinforcing the sound pressure due to the passive driving of the active radiator 40 through the active driving by which the active radiator 40 complements the passive driving. Therefore, although the size of the transducer 30 and the enclosure 20 is restricted, it is possible for the speaker 10 of the electronic apparatus 1 to output an enhanced bass component.

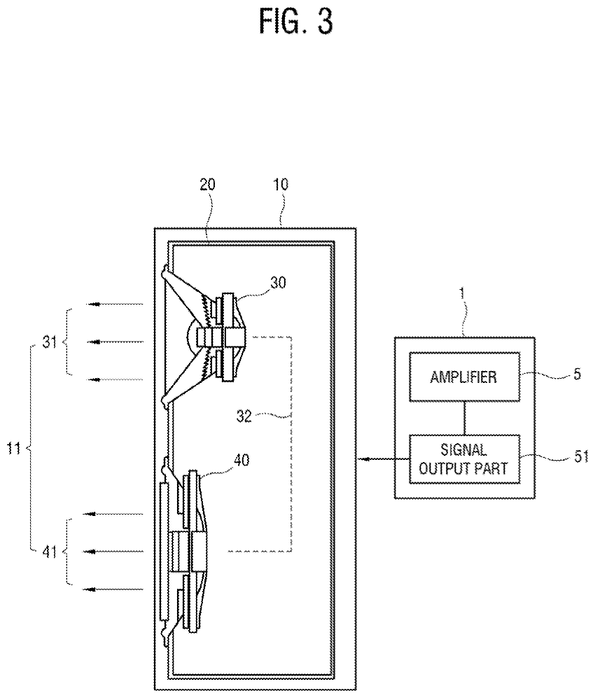

FIG. 3 illustrates an electronic apparatus 1 according to still another embodiment of the disclosure. As illustrated in FIG. 3, the electronic apparatus 1 according to the embodiment includes the amplifier 5 which provides the driving signal to the speaker 10 is provided externally. Below, the electronic apparatus 1 of FIG. 3 will be mainly described on differences from that of FIGS. 1 and 2, and description redundant to FIGS. 1 and 2 will be omitted.

As illustrated FIG. 3, the electronic apparatus 1 according to the embodiment outputs the sound wave through the speaker 10 which is provided outside the electronic apparatus 1. For example, the electronic apparatus 1 may include an amplifier unit or module. However, the electronic apparatus 1 is not limited thereto but may be embodied as an audio device, a smart phone, a tablet, a personal computer, a wearable device such a smart watch, a multimedia player, a home appliance such as a refrigerator, etc., which include the amplifier unit or module. Also, the speaker 10 may be embodied as a separate speaker, a speaker unit, a speaker module, an ultra-small portable speaker, an artificial intelligence speaker, a home theater, etc., which are provided outside the electronic apparatus 1.

The electronic apparatus 1 according to the embodiment includes the amplifier 5 and a signal output part 51. The amplifier 5 performs a signal process such as amplification of the level or the output of the sound signal so that the speaker 10 outputs the total target value sound pressure 11 based on the sound signal. Specifically, the amplifier 5 processes the first driving signal so that the transducer 30 of the speaker 10 outputs the sound pressure 31 based on the sound signal. The amplifier 5 processes the second driving signal so that the active radiator 40 reinforces the output sound pressure due to the passive driving through the active driving and outputs the target value sound pressure 41. Therefore, the speaker 10 outputs the total target value sound pressure 11 based on the output sound pressure 31 of the transducer 30 and the target value output sound pressure 41 of the active radiator 40. Meanwhile, the amplifier 5 performs a signal process based on a predetermined gain so that the speaker 10 outputs the total target value sound pressure 11.

The signal output part 51 outputs the driving signal which is processed by the amplifier 5 to the speaker 10. The signal output part 51 may include a wired or wireless output part to output the driving signal to the speaker 10. For example, the signal output part 51 may include the wired output part such as an optical cable, an RCA cable, a speakon cable, etc. or the wireless output part such as Bluetooth, Bluetooth low energy (BLE), infrared data association (IrDA), ZigBee, Wi-Fi Direct (WFD), ultra-wideband (UWB), etc. However, the signal output part 51 is not limited thereto but may include various wired or wireless output parts and be embodied as a single module which includes two or more wired or wireless output parts.

Meanwhile, FIG. 3 does not limit the configurations of the electronic apparatus 1, and thus the electronic apparatus 1 may exclude a part of the configurations shown in FIG. 3 or include another configuration not shown in FIG. 3.

In this way, the electronic apparatus 1 according to the embodiment outputs the driving signal to the speaker 10 and allows the active radiator 40 of the speaker 10 to output the target value sound pressure 41 by reinforcing the sound pressure due to the passive driving of the active radiator 40 through the active driving by which the active radiator 40 complements the passive driving. Therefore, although the size of the transducer 30 and the enclosure 20 is restricted, it is possible for the speaker 10 of the electronic apparatus 1 to output an enhanced bass component.

FIG. 4 illustrates an example of the speaker 10 in FIGS. 1 to 3. As illustrated in FIG. 4, the speaker 10 according to the embodiment includes the enclosure 20, the transducer 30 and the active radiator 40, and may further include a first amplifier 21, a second amplifier 22 and a filter 23. Below, referring to FIG. 4, the active driving by the active radiator 40 will be mainly described on differences from that of FIGS. 1 to 3, and description redundant to FIGS. 1 to 3 will be omitted.

The first amplifier 21 outputs the first driving signal to the transducer 30 based on the input sound signal. The first driving signal may be obtained by amplifying the level or the output of the sound signal, and the first amplifier 21 may adjust a predetermined gain to change the level or the output of the first driving signal.

The transducer 30 receives the first driving signal from the first amplifier 21 and performs the amplitude movement according to the first driving signal to output the sound pressure 31. The transducer 30 generates the front wave 31 which is outward from the enclosure 20 and the rear wave 32 which is inward to the enclosure 20. The change in the air pressure in the enclosure 20 due to the rear wave 32 of the transducer 30 allows the active radiator 40 to perform the passive driving and output the sound pressure.

Meanwhile, the second amplifier 22 receives the sound signal from the signal processor and outputs the second driving signal to the active radiator 40 based on the sound signal so that the active radiator 40 performs the active driving which complements the passive driving based on the second driving signal. The second driving signal may be obtained by amplifying the level or the output of the sound signal to correspond to the target value output sound pressure 41 of the active radiator 40. For example, the level of the second driving signal is determined such that a sum of the amplitude movement of the active radiator 40 due to the rear wave 32 and the amplitude movement of the active radiator 40 due to the second driving signal corresponds to the target value output sound pressure 41 of the active radiator 40.

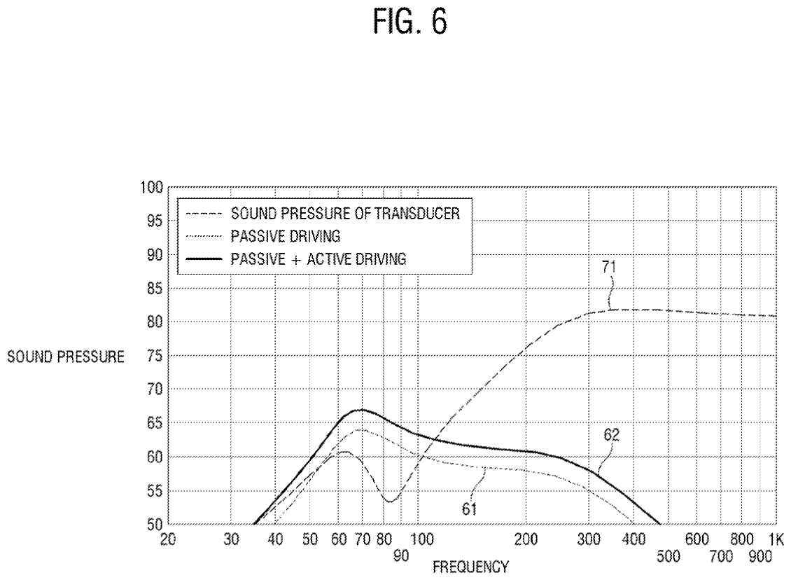

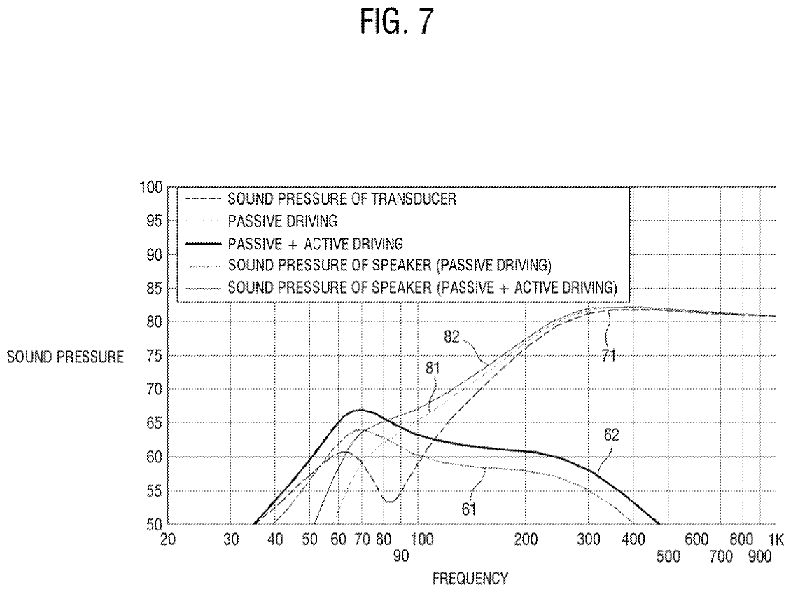

The second amplifier 22 may adjust a gain to change the level or the output of the second driving signal. Described in more detail referring to FIGS. 6 and 7, the second amplifier 22 has a predetermined gain such that the active radiator 40 reinforces the output sound pressure 61 due to the passive driving by the active driving to output the target value sound pressure 62. That is, because the level or the output of the second driving signal which is output to the active radiator 40 is determined in accordance with the predetermined gain, the target value output sound pressure 62 of the active radiator 40 is determined by adjusting the gain.

Also, because the first amplifier 21 has a predetermined gain such that the transducer 30 outputs the sound pressure 71 and the output sound pressure 71 of the transducer 30 is determined by adjusting the gain, the total target value sound pressure 82 is determined by adjusting the gain of at least one of the first amplifier 21 or the second amplifier 22. That is, since the target value output sound pressure 62 of the active radiator is determined by excluding a portion due to the output sound pressure 71 of the transducer 30 from the total target value sound pressure 82 of the speaker 10, the total target value sound pressure 82 of the speaker 10 is determined by adjusting the gain of at least one of the first amplifier 21 or the second amplifier 22. However, the adjustment of the gain is not limited to be predetermined but may be determined by the control of the processor or be changed.

The filter 23 performs filtering with respect to the low frequency range of the sound signal and outputs the filtered sound signal to the second amplifier 22. In this case, the second amplifier 22 outputs the second driving signal, which is obtained by amplifying the level or the output of the filtered sound signal, to the active radiator 40 and allows the active radiator 40 to perform the amplitude movement in the low frequency range.

The filtering characteristic of the filter 23 is determined by counter-electromotive force which is generated by a coil 47 of the active radiator 40. For example, when the coil 47 vibrates based on the second driving signal which is applied to the coil 47, the filtering characteristic is determined based on the counter-electromotive force which has at least one of a voltage or a phase at frequency that happens in response to the vibration of the coil 47. If the voltage at frequency of the counter-electromotive force has a peak near 80 Hz, the filtering characteristic may be set to have a peak near 80 Hz, whereas if the phase at frequency of the counter-electromotive force decreases slowly near to 80 Hz and quickly near from 100 Hz, the filtering characteristic may be set to decrease slowly near to 80 Hz and quickly near from 100 Hz. however, the filtering characteristic of the filter 23 is not limited thereto but may be set by various methods according to the environment of filtering.

In this way, the speaker 10 according to the embodiment allows the active radiator 40 to output the target value sound pressure 62 by the active driving through the second amplifier and outputs the total target value sound pressure 82. Therefore, although the size of the transducer 30 and the enclosure 20 is restricted, it is possible for the speaker 10 to output an enhanced bass component.

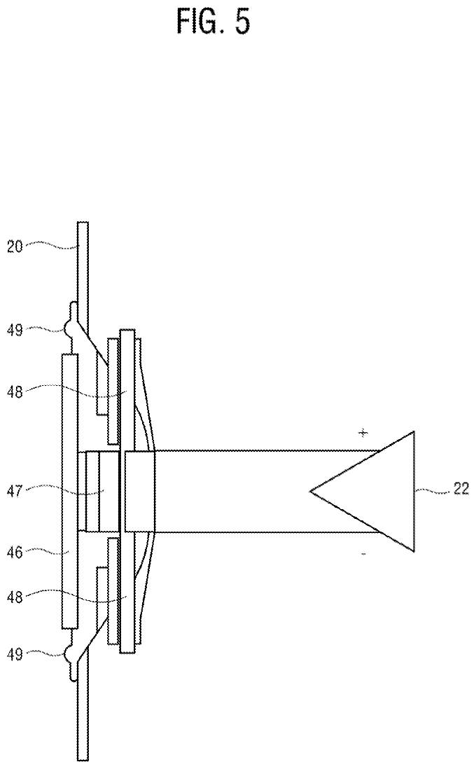

FIG. 5 illustrates an example of the active radiator 40 of FIGS. 1 to 3. As illustrated in FIG. 5, the active radiator 40 includes a vibration system such as a diaphragm 46, a coil 47, a magnet 48, an edge 49, etc.

The diaphragm 46 is embodied of paper, polypropylene, plastic synthetic resin, etc. which is easy to vibrate, and generates the sound wave with the sound pressure through the vibration. The diaphragm 46 allows the active radiator 40 to output the target value sound pressure 62 by the active driving which complements the vibration due to the passive driving.

The coil 47 is connected to the second amplifier 22 and receives the second driving signal from the second amplifier 22. The coil 47 vibrates in accordance with the polarity which changes based on the second driving signal. The coil 47 is coupled with the diaphragm 46 and allows the diaphragm 46 to perform the amplitude movement in accordance with the vibration.

The magnet 48 forms a magnetic field to the coil 47 and allows the coil 47 to vibrate where the polarity changes based on the second driving signal. The edge 49 is coupled to the diaphragm 46 and allows the diaphragm 46 to perform the amplitude movement. However, the vibration system of the active radiator 40 is not limited thereto but may further include a frame, which fastens the active radiator 40, a damper, which is provided between the diaphragm 46 and the coil 47 and modulates the vibration of the diaphragm 46, etc.

The active radiator 40 outputs the target value sound pressure 62 by the amplitude movement of the vibration system, where a vibration frequency range of the active radiator 40 is determined by correlation between acoustic resistance, which is formed by the weight and compliance of the vibration system, and air volume in the enclosure 20. Although the vibration frequency range of the active radiator 40 may be confined if the size of the enclosure 20 is restricted, the vibration frequency range can be expanded by the active driving of the active radiator 40. This will be described in detail with reference to FIGS. 6 and 7.

FIGS. 6 and 7 illustrate an example where the target value sound pressure is output by the active driving of FIG. 4. First, referring to FIG. 6, the transducer 30 outputs the sound pressure 71 in the high frequency range and the low frequency range according to the first driving signal. The output sound pressure 71 of the transducer 30 has a roll-off range at the low frequency range where the sound pressure decreases quickly.

The active radiator 40 outputs the sound pressure 61 through the passive driving in which the amplitude movement is performed according to the rear wave 32, while outputting the target value sound pressure 62 by complementing the amplitude movement due to the passive driving through the active driving.

Therefore, as illustrated in FIG. 6, the active radiator 40 according to the embodiment is able to compensate the roll-off and enhance the range of the output sound pressure as well as the level of the output sound pressure by complementing the passive driving through the active driving.

Next, referring to FIG. 7, the total output sound pressure 81 of the speaker 10 due to the passive driving is obtained by a sum of the output sound pressure 71 of the transducer 30 and the output sound pressure 61 due to the passive driving of FIG. 6. Also, the total output sound pressure 82 of the speaker 10 due to the active driving together with the passive driving is obtained by a sum of the output sound pressure 71 of the transducer 30 and the output sound pressure 62 due to the passive driving and the active driving of FIG. 6.

In this way, although the size of the transducer 30 and the enclosure 20 is restricted, the total output sound pressure 82 of the speaker 10 due to the active driving is able to output the sound pressure which has the level and the range that are more enhanced than the total output sound pressure 81 of the speaker 10 due to the passive driving. Further, the level and the range of the total output sound pressure 82 of the speaker 10 due to the active driving can be variable. For example, the total output sound pressure 82 of the speaker 10 may be variably determined by adjusting the gain of at least one of the first amplifier 21 or the second amplifier 22 of FIG. 4.

Although the exemplary embodiments have been described, the disclosure is not limited thereto and may be variously embodied within the scope of the claims.

1. An electronic apparatus comprising:
a housing;
a speaker provided in an enclosure of the housing and configured to output a sound wave based on a sound signal, the speaker comprising
a transducer configured to perform an amplitude movement based on a first driving signal, and
an active radiator configured to perform an amplitude movement based on a rear wave due to the amplitude movement of the transducer and a second driving signal; and
an amplifier configured to output the first driving signal corresponding to the sound signal and the second driving signal which complements the amplitude movement of the active radiator based on the rear wave of the transducer and allows an output sound pressure of the active radiator to be a target value.

2. The electronic apparatus according to claim 1, further comprising a filter configured to perform a filtering with respect to a frequency range of the sound signal to allow the second driving signal to have the frequency range.

3. The electronic apparatus according to claim 2, wherein the frequency range is determined by at least one of weight of a vibration system of the active radiator or air volume in the enclosure.

4. The electronic apparatus according to claim 1, wherein the target value of the output sound pressure of the active radiator is determined by excluding a portion due to the output sound pressure of the transducer from a target value of a total output sound pressure of the speaker.

5. The electronic apparatus according to claim 1, wherein a level of the second driving signal is determined such that a sum of the amplitude movement of the active radiator due to the rear wave and the amplitude movement of the active radiator due to the second driving signal corresponds to the output sound pressure having the target value.

6. The electronic apparatus according to claim 1, further comprising a display of a panel shape,
wherein the housing has a rear face covering rear of the display, and
the enclosure is provided between the rear face of the housing and the display.

7. An electronic apparatus comprising:
a signal output part configured to output a first driving signal and a second driving signal to a speaker, the speaker comprising a transducer configured to perform an amplitude movement based on the first driving signal, and an active radiator configured to perform an amplitude movement based on a rear wave due to the amplitude movement of the transducer and the second driving signal; and
an amplifier configured to perform a signal process to output through the signal output part the first driving signal corresponding to a sound signal and the second driving signal which complements the amplitude movement of the active radiator based on the rear wave of the transducer and allows an output sound pressure of the active radiator to be a target value.

8. The electronic apparatus according to claim 7, further comprising a filter configured to perform a filtering with respect to a frequency range of the sound signal to allow the second driving signal to have the frequency range.

9. The electronic apparatus according to claim 8, wherein the frequency range is determined by at least one of weight of a vibration system of the active radiator or air volume in the enclosure.

10. The electronic apparatus according to claim 7, wherein the target value of the output sound pressure of the active radiator is determined by excluding a portion due to the output sound pressure of the transducer from a target value of a total output sound pressure of the speaker.

11. The electronic apparatus according to claim 7, wherein a level of the second driving signal is determined such that a sum of the amplitude movement of the active radiator due to the rear wave and the amplitude movement of the active radiator due to the second driving signal corresponds to the output sound pressure having the target value.

12. A speaker comprising:
an enclosure;
a transducer provided in the enclosure and configured to perform an amplitude movement based on a first driving signal;
an active radiator provided in the enclosure and configured to perform an amplitude movement based on a rear wave due to the amplitude movement of the transducer and a second driving signal; and
an amplifier configured to output the first driving signal corresponding to a sound signal which is input and the second driving signal which complements the amplitude movement of the active radiator based on the rear wave of the transducer and allows an output sound pressure of the active radiator to be a target value.

13. The speaker according to claim 12, further comprising a filter configured to perform a filtering with respect to a frequency range of the sound signal to allow the second driving signal to have the frequency range.

14. The electronic apparatus according to claim 13, wherein the frequency range is determined by at least one of weight of a vibration system of the active radiator or air volume in the enclosure.

15. The electronic apparatus according to claim 12, wherein the target value of the output sound pressure of the active radiator is determined by excluding a portion due to the output sound pressure of the transducer from a target value of a total output sound pressure of the speaker.
